(19) United States
(12) Patent Application Publication
(10) Pub. No.: US 2006/0068619 A1
(43) Pub. Date: Mar. 30, 2006

(54) Rear-projection type imaging device

(75) Inventors: Koichi Tajima, Takefu-city (JP); Kenji Shimoshita, Takefu-city (JP); Takashi Tokuda, Takefu-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Takefu-city (JP)

(21) Appl. No.: 11/232,946

(22) Filed: Sep. 23, 2005

(30) Foreign Application Priority Data
Sep. 28, 2004 (JP) 2004-281436

(51) Int. Cl. H05K 1/00

(52) U.S. Cl. 439/79

(57) ABSTRACT

To provide a device capable of effectively shielding noise which constitutes interference is provided without sacrificing miniaturization. A power supply circuit board 60 and an analog signal processing substrate 61 are arranged side by side backward and forward centered on a projection unit 30 and a lamp drive circuit board 64 is disposed at a position far from the analog signal processing substrate 61 across the projection unit 30. A driver circuit board 31, digital circuit board 62 and scaler circuit board 63 are housed in shield cases 39, 70, 71, the shield case 70 is disposed upright so as to separate the power supply circuit board 60 and analog signal processing substrate 61 from the driver circuit board 31, and the three sides of the driver circuit board 31 are surrounded with the shield cases 70, 71 and an uprising section 35b of a support frame 35.

The present application is based on and claims priority of Japanese patent application No. 2004-281436 filed on Sep. 28, 2004, the entire contents of which are hereby incorporated by reference.

### BACKGROUND OF THE INVENTION

1. Field of the Invention

The present invention relates to a rear-projection type imaging device which reflects an optical image projected from a projection unit and projects the image onto a screen which is exposed on one side of a housing.

2. Description of the Related Art

Conventionally, as a rear-projection type imaging device such as a rear projector, one described in Japanese Patent Laid-Open Publication No. 2003-337377 (Patent Document 1) is known. The rear-projection type imaging device disclosed here incorporates in a box-shaped housing, a projection unit which modulates a beam projected from a lamp unit according to image information, forms an optical image and projects an enlarged image of the optical image, a reflecting mirror which reflects the projected image and a screen which projects the optical image reflected from the reflecting mirror, and projects the optical image reflected from the reflecting mirror onto the screen.

Such a rear projector reflects an optical image and projects the reflected image onto a screen, and can thereby display a video image on a large screen compared to a conventional television receiver which displays images on a CRT or the like, and therefore it is becoming widespread for use in a home theater or the like in households in recent years. On the other hand, there is a demand for a home theater in households which will occupy as little space as possible by designing layouts of not only components like a lamp unit making up the rear projector, a projection unit and a reflecting mirror but also various circuit boards such as a driver circuit board which drives the projection unit, a power supply circuit board which supplies power to the projection unit, a digital circuit board which processes a digital signal such as a video signal, an analog signal processing substrate which processes an analog signal such as an audio signal, a scaler circuit board which converts the signal sent from the analog signal processing substrate to a predetermined display format (resolution) so as to arrange them as intensively as possible to thereby reduce the overall size and make the device as slim as possible. On the other hand, when various circuit boards are arranged intensively in this way, noise is emitted from the circuit boards and particularly in recent years, integrated circuit (IC) substrates for such circuit units are being designed increasingly intended for high-frequency specifications, which causes various types of trouble. For example, in the case of a rear-projection type imaging device, such noise reduces electromagnetic shield performance or causes unnecessary reflected light to pass, and therefore when various circuit boards are intensively arranged to reduce the size of the device, noise control becomes extremely important. In the rear-projection type imaging device, a lamp operating as a light source generates high heat, which causes its life cycle to become relatively short and makes it indispensable to replace the lamp. For these reasons, it is also an important issue how to facilitate replacement of lamps, assure safe replacement work and facilitate maintenance work such as focusing of an optical image projected on a screen.

### SUMMARY OF THE INVENTION

The present invention is intended to solve the above described problems and it is an object of the present invention to provide a rear-projection type imaging device with such a layout that makes the entire device compact and slimmer, capable of effectively shielding noise which constitutes interference without sacrificing the miniaturization and at the same time providing excellent maintenability.

The rear-projection type imaging device according to a first aspect of the present invention is a rear-projection type imaging device including a lamp unit, a projection unit which modulates a beam projected from the lamp unit according to image information, forms an optical image and projects an enlarged image of the optical image, a reflecting mirror which reflects the optical image projected from the projection unit, a screen exposed on one side of the housing, for projecting the optical image from the reflecting mirror and a housing which houses the lamp unit, projection unit, reflecting mirror and screen, wherein a support frame for integrating the projection unit and a driver circuit board which drives the projection unit and fixing the projection unit and driver circuit board to the housing is provided, the support frame comprises at least a bottom plate fixed to the housing and an uprising plate standing from one end of the bottom plate, the projection unit is fixed to the uprising plate so as to float from the bottom plate and at least part of the driver circuit board is disposed in a space formed between the projection unit and the bottom plate and the driver circuit board is fixed to the bottom plate.

According to the structure of the first aspect of the present invention, the projection unit is made to float from the bottom plate of the support frame, and therefore the projection unit is allowed to set the projection unit at a highest possible position within a range not interfering the optical path of the optical image reflected from the reflecting mirror, which suppresses the total height of the housing to a low level. Furthermore, having the projection unit float causes a space for placing the driver circuit board to be formed between the projection unit and bottom plate and when the driver circuit board is fixed in the space, part of the driver circuit board overlaps with the projection unit in the vertical direction, which makes it possible to effectively use the space formed in the lower part of the projection unit as a mounting space for the driver circuit board.

The rear-projection type imaging device according to a second aspect of the present invention is the rear-projection type imaging device according to the first aspect of the present invention, wherein the housing includes at least a power supply circuit board which supplies power to a drive control section or the like of the optical unit, a digital circuit board which processes a digital signal such as a video signal sent from a digital tuner or the like, an analog signal processing substrate which processes an analog signal such as an audio signal sent from an external terminal or the like and a scaler circuit board which converts a display format based on the signal sent from the analog signal processing substrate, shield cases which cover at least the driver circuit board, digital circuit board and scaler circuit board are provided, the shield cases housing the digital circuit board and scaler circuit board are disposed upright close to two sides intersecting each other at right angles of the driver circuit board and the shield cases and uprising plate of the support frame are arranged so as to surround three sides of the driver circuit board.

According to the structure of the second aspect of the present invention, the three sides of the driver circuit board are surrounded by the shield case housing the digital circuit board, the shield case housing the scaler circuit board and the uprising plate and the driver circuit board itself is covered with a shield case, and therefore it is possible to assure electromagnetic shielding, shield high-frequency noise which gets mixed in with the driver circuit board through two pairs of shield cases and the uprising plate and thereby effectively suppress the mixing of noise into the driver circuit board.

The rear-projection type imaging device according to a third aspect of the present invention is the rear-projection type imaging device according to the second aspect of the present invention, wherein the projection unit is disposed at substantially the center of the housing, the analog signal processing substrate and power supply circuit board are arranged side by side on one side of the projection unit and the shield case which houses the digital circuit board is interposed between the analog signal processing substrate, power supply circuit board and driver circuit board so that the shield case separates the analog signal processing substrate and power supply circuit board from the driver circuit board.

According to the structure of the third aspect of the present invention, noise radiated from the analog signal processing substrate, power supply circuit board or driver circuit board is shielded by the shield case housing the digital circuit board, and therefore it is possible to effectively suppress the mixing of noise between the substrates.

The rear-projection type imaging device according to a fourth aspect of the present invention is the rear-projection type imaging device according to the third aspect of the present invention, further comprising a lamp drive circuit board which drives the lamp unit, wherein the lamp drive circuit board is disposed at a position far from the analog signal processing substrate with the projection unit interposed in between.

According to the structure of the fourth aspect of the present invention, the lamp drive circuit board generates a high voltage (approximately 1000 V) to turn on the lamp, which causes high-frequency noise to be produced. However, since the lamp drive circuit board is disposed at a position as far as possible from the analog signal processing substrate with the projection unit interposed in between, it is possible to effectively inhibit the high-frequency noise radiated from the lamp drive circuit board into the analog signal processing substrate.

The rear-projection type imaging device according to a fifth aspect of the present invention is the rear-projection type imaging device according to the first aspect of the present invention, wherein a lamp replacement section for attaching/detaching the lamp provided in the lamp unit is formed in a substrate unmounted area inside the housing.

According to the structure of the fifth aspect of the present invention, when the lamp is replaced, the lamp is replaced through the lamp replacement opening and since the lamp replacement opening is formed in the substrate unmounted area where no circuit board or electronic parts or the like exist, which prevents the operator from mistakenly touching the circuit board or electronic parts when replacing the lamp.

The rear-projection type imaging device according to a sixth aspect of the present invention is the rear-projection type imaging device according to the first aspect of the present invention, wherein the projection unit comprises a focusing function which focuses the projection lens and a working opening which allows the focusing function to be operated from outside the housing is provided on the front side of the housing.

According to the structure of the sixth aspect of the present invention, the operator can perform focusing of the projection lens while checking a screen projected on the screen.

### BRIEF DESCRIPTION OF THE DRAWINGS

FIG. 1 is a cross section showing a schematic structure of a rear projector according to an embodiment of the present invention viewed from one side;

FIG. 2 is a plan cross section of the rear projector according to this embodiment;

FIG. 3 is a perspective view of the rear projector according to this embodiment viewed from the front;

FIG. 4 is a plan view of the layout of the substrate according to this embodiment; and

FIG. 5 is a side view of the projection unit showing a focusing operation of the projection unit according to this embodiment.

### DETAILED DESCRIPTION OF THE PREFERRED EMBODIMENTS

An embodiment as the best mode for implementing the present invention will be explained below. However, it goes without saying that the present invention is also easily applicable to structures other than that explained in the embodiment within a range not departing from the essence of the present invention.

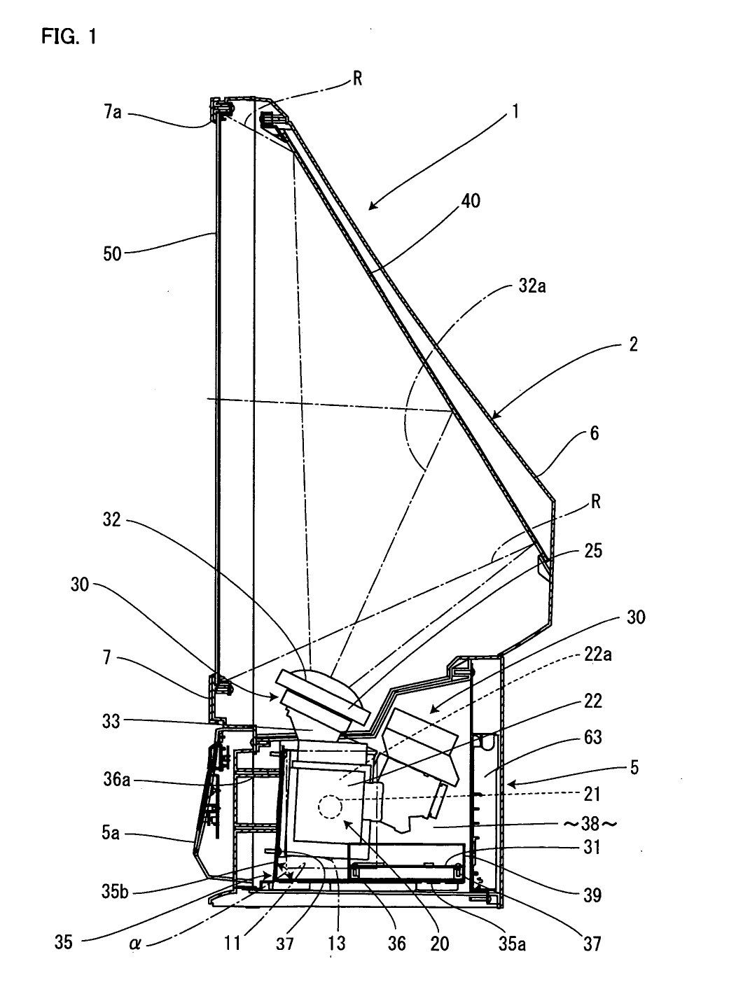

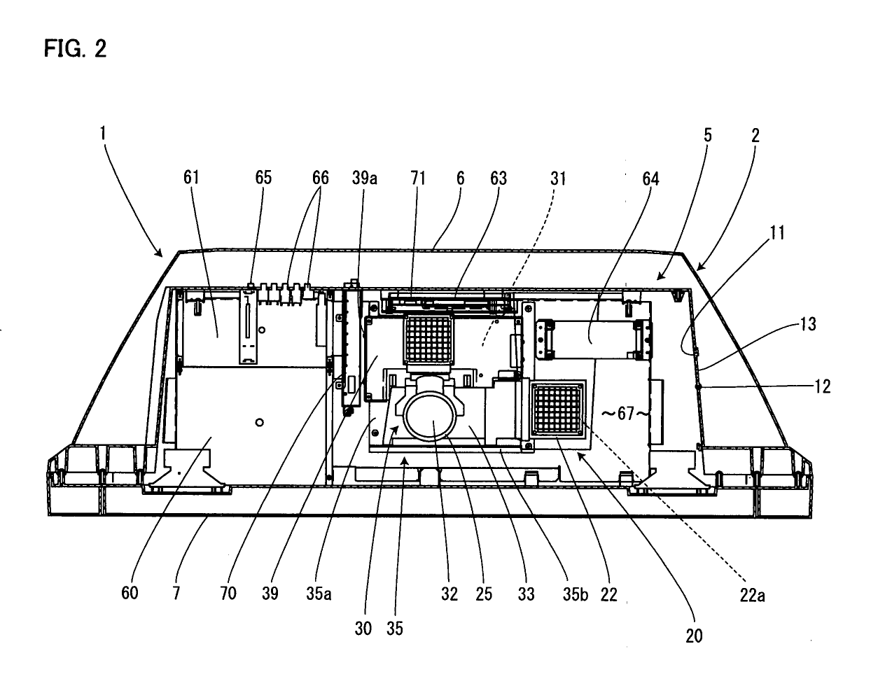

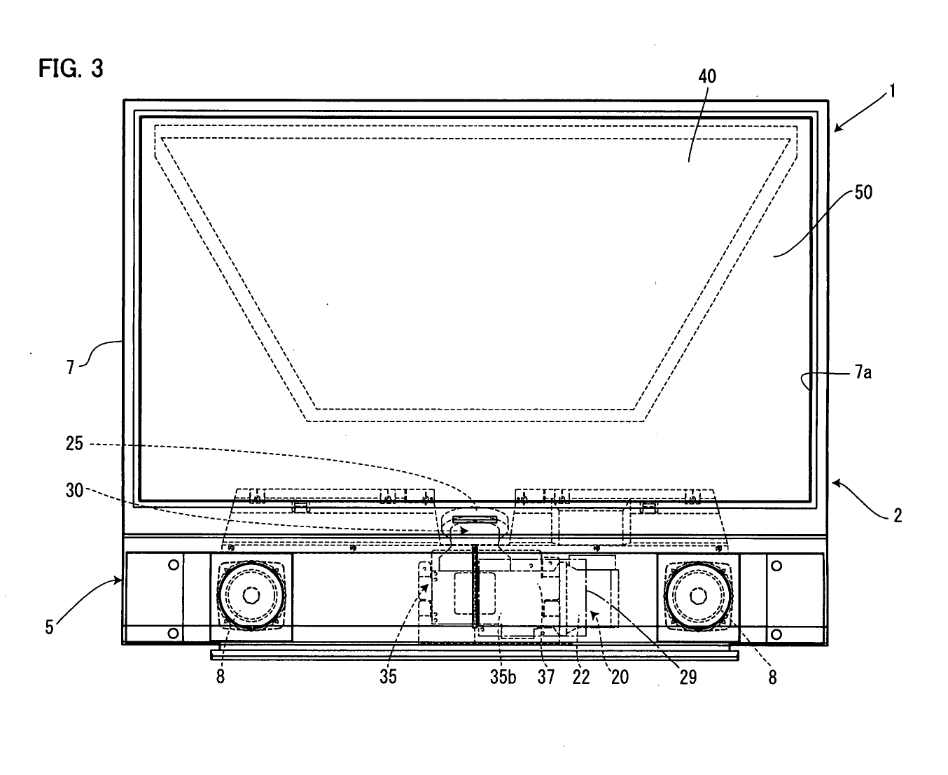

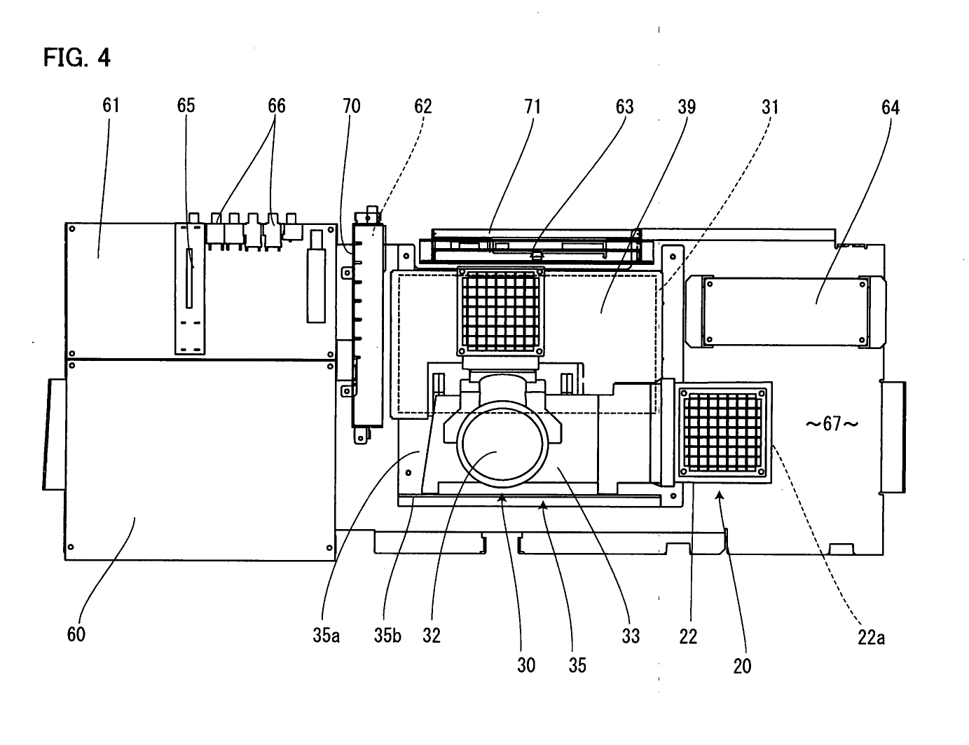

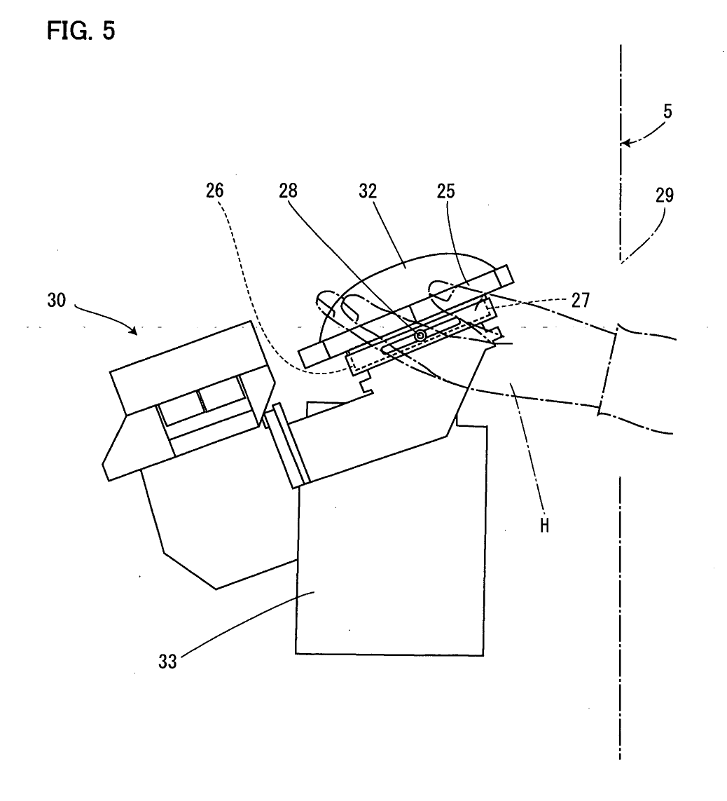

FIG. 1 is a cross section showing a schematic structure of a rear projector as a rear-projection type imaging device according to the present invention viewed from one side, FIG. 2 is a plan cross section, FIG. 3 is a perspective view viewed from the front, FIG. 4 is a plan view of the layout of the substrate and FIG. 5 is a side view of a projection unit showing a focusing operation of the projection unit. With reference to the above described drawings, the main structure of the rear projector 1 will be explained. The rear projector 1 modulates a beam emitted from a light source and forms an optical image according to image information, and projects an enlarged image of this optical image onto a screen, and is mainly constructed of a cabinet 2 making up a housing, a projection unit 30 disposed inside the cabinet 2, a reflecting mirror 40 which reflects an optical image projected from this projection unit 30 and a screen 50 onto which the optical image from the reflecting mirror 40 is projected.

The cabinet 2 is made up of a lower cabinet 5, a back cabinet 6 and a front cabinet 7 which are fixed above this lower cabinet 5. The projection unit 30 is fixed to the inner bottom section of the lower cabinet 5 and a pair of right and left speakers 8, 8 are also fixed thereto. Furthermore, the reflecting mirror 40 is fixed to the back cabinet 6 and the screen 50 is fixed bordering a display window 7a formed on the front of the front cabinet 7 facing this reflecting mirror 40.

The projection unit 30 is a unit which optically processes a beam irradiated from a lamp unit 20 which is a light source, forms an optical image corresponding to image information and projects an enlarged image of this optical image, and is provided with a driver circuit board 31 which drives the projection unit 30 and a projection lens 32 or the like as main components. Furthermore, the lamp unit 20 is provided with a high-intensity lamp 21 such as a halogen lamp or metal halide lamp as its light source and houses this high-intensity lamp 21 in a lamp housing 22. The lamp housing 22 includes a fan (not shown) and releases the heat produced by driving of the fan in the lamp 21 to the outside. The lamp 21 housed in the lamp housing 22 needs to be replaced when it reaches the end of its life. To allow the user to replace the lamp in the lamp housing 22 at thus time, an opening 11 which is a lamp replacement section is formed on one side of the lower cabinet 5 at a position corresponding to the lamp housing 22 as shown in FIG. 2. This opening 11 is normally covered with an opening/closing cover 13 mounted in the lower cabinet 5 through a hinge mechanism 12 or the like and when replacing the lamp 21, the user can open the cover 13 and open the opening 11 to attach/detach the lamp 21. Furthermore, the projection lens 32 is fixed to a casing 33 of the projection unit 30. Though not shown, components such as a relay lens which transforms light from the lamp 21 into substantially parallel light, a polarization beam splitter which divides the light passing through the relay lens into transmitted light and reflected light and a polarization/conversion element made up of a reflective type liquid crystal panel which modulates the light reflected/transmitted by the polarization beam splitter into video image light are fixed as one body or unitized inside the casing 33, and the video image light modulated by the polarization/conversion element is projected onto the reflecting mirror 40 through the projection lens 32 built in the top surface of the casing 33. In this way, by coupling the casing 33 of the projection unit 30 which unitizes the various components and the lamp housing 22 of the lamp 21, it is possible to unitize the projection unit 30 and lamp unit 20, further integrate these unitized projection unit 30 and the driver circuit board 31 through a metal support frame 35 and fix it substantially at the center of the lower cabinet 5. Furthermore, as shown in FIG. 5, a male screw section 26 for focusing is formed in a holding frame 25 in which the projection lens 32 is built, a female screw section 27 into which the male screw section 26 is screwed is formed in the casing 33 of the projection unit 30 and a fixing screw 28 which presses the female screw section 27 to fix the holding frame 25 is screwed in the casing 33. To perform focusing of the projection unit 30, the holding frame 25 is turned to adjust the height of the projection unit 30 and the projection lens 32 is focused with respect to a plurality of mirror groups built in the casing 33 and then the position of the projection lens 32 in the height direction is fixed using a fixing screw 28. The male screw section 26, female screw section 27 and fixing screw 28 constitute a focusing mechanism of the projection unit 30. Furthermore, as shown in FIG. 5, a working opening 29 is formed on the front of the lower cabinet 5 to allow the user to put the hand H into the housing through the working opening 29 so as to focus the projection unit 30 and fix the projection lens 32 after the focusing from the front side of the rear projector 1. Here, the working opening 29 is normally covered with a detachable decorative panel 5a.

The support frame 35 consists of a bottom plate 35a and an uprising section 35b positioned standing from one side of this bottom plate 35a, forming substantially an L shape as a whole and the casing 33 of the projection unit 30 integrated with the lamp unit 20 is screwed into the uprising section 35b. Furthermore, a mounting piece 36 for fixing the driver circuit board 31 to drive the projection unit 30 is formed by shaving in the bottom plate 35a and the driver circuit board 31 which is placed substantially horizontal to this mounting piece 36 is fixed using a screw 37. In this way, the support frame 35 to which the projection unit 30, lamp unit 20 and driver circuit board 31 are fixed is fixed to a boss section 36a formed at the bottom of the lower cabinet 5 and the front of the lower cabinet 5 as an integral part using the screw 37. Furthermore, the projection unit 30 fixed to the support frame 35 is fixed to an upper part of the uprising section 35b so as to float from the bottom plate 35a fixed to the bottom of the lower cabinet 5. That is, as shown in FIG. 1, the projection unit 30 can be set the highest possible position within a range not interfering with the optical path R of an optical image reflected from the reflecting mirror 40, and therefore it is possible to suppress the total height of the rear projector 1 to a low level. Moreover, as shown in FIG. 1, the uprising section 35b which fixes the projection unit 30 is tilted inward by 3° with respect to the normal, that is, the angle of inclination α of the uprising section 35b with respect to the bottom plate 35a is set to 87°. Thus, when the uprising section 35b is tilted inward by 3°, the optical axis 32a of the projection lens 32 can be tilted toward the back cabinet 6. This allows the reflecting mirror 40 which reflects an optical image from the projection lens 32 to tilt by 1.5° in the uprising direction, and can thereby make the cabinet 2, or by extension, the rear projector 1 slimmer. Furthermore, having the projection unit 30 float causes a space 38 for placing the driver circuit board 31 to be formed between the projection unit 30 and bottom plate 35a and when the driver circuit board 31 is fixed in the space 38, part of the driver circuit board 31 overlaps with the projection unit 30 in the vertical direction. This makes it possible to effectively use the space 38 formed in the lower part of the projection unit 30 as a mounting space for the driver circuit board 31. Furthermore, a shield case 39 to cover the driver circuit board 31 is screwed into the bottom plate 35a of the support frame 35.

As described above, the projection unit 30 and driver circuit board 31 are fixed at substantially the center of the lower cabinet 5 by the support frame 35 and various substrates for driving and controlling the projection unit 30 and rear projector 1 are fixed to the bottom of the lower cabinet 5 centered on the projection unit 30. FIG. 4 is a plan view showing layouts of the respective substrates and as shown in the same figure, when the screen 50 is assumed to be located on the front side, a power supply circuit board 60 and an analog signal processing substrate 61 are arranged side by side to the left of the projection unit 30 and a digital circuit board 62 is interposed between the power supply circuit board 60, analog signal processing substrate 61 and the projection unit 30. Furthermore, a scaler circuit board 63 is disposed on the back side of the projection unit 30 and a lamp drive circuit board 64 is disposed on the back side of the lower cabinet 5 to the right of the projection unit 30 which corresponds to the lamp unit 20 side in the figure.

The power supply circuit board 60 supplies power to the lamp drive circuit board 64, signal lines of various sections and a control microcomputer (not shown) . An analog tuner 65 and input/output terminals 66 are mounted on the analog signal processing substrate 61 and an analog signal input from the analog tuner 65 is output from the input/output terminal 66 to an external apparatus and analog signals input from the input/output terminals 66 are output to the scaler circuit board 63. Furthermore, the analog signal processing substrate 61 is provided with an audio block for generating an audio multiplexed signal and surrounding signal, whereby an analog signal such as audio signal is processed. The digital circuit board 62 is provided with a digital tuner, a digital tuner input circuit and a D/A converter (not shown) which converts a digital signal to an analog signal and sends a digital signal to the analog signal processing substrate 61 and scaler circuit board 63. The scaler circuit board 63 converts a signal sent from the analog signal processing substrate 61 to a predetermined display format (resolution) and carries out processing for displaying the signal mainly on the screen 50. Furthermore, the scaler circuit board 63 is provided with a video decoder circuit (not shown) and has the function of decoding a compressed input signal. The lamp drive circuit board 64 is a lamp control substrate provided with a transformer which controls a voltage supplied from the power supply circuit board 60, generates a high voltage (approximately 1000 V) to turn on the lamp 21 and outputs the high voltage to the driver circuit board 31 and the driver circuit board 31 is a control substrate for the projection unit 30, which controls ON/OFF of the lamp 21 based on the voltage output from the lamp drive circuit board 64 and white balance and brightness or the like of the display screen. The lamp drive circuit board 64 disposed to the right of the projection unit 30 which is the lamp unit 20 side is disposed at the back on the side of the lamp unit 20, the space formed between the lamp unit 20 and the opening 11 formed on the side of the lower cabinet 5 is a substrate unmounted area 67 where no circuit board or electronic parts or the like exist, a lamp replacement opening 22a is formed in the lamp housing 22 which houses the lamp 21 bordering this substrate unmounted area 67, and during replacement of the lamp 21 when the user puts his/her hand into the housing through the opening 11 of the lower cabinet 5 and replaces the lamp 21 from the lamp replacement opening 22a of the lamp housing 22, it is possible to prevent the user's hand from touching the circuit board and electronic parts. Furthermore, the digital circuit board 62 and scaler circuit board 63 are surrounded by metal shield cases 70, 71. These shield cases 70, 71 have the function of preventing leakage of electromagnetic noise and these shield cases 70, 71 are disposed upright along two sides intersecting each other at right angles of the driver circuit board 31, that is, according to this embodiment, the shield case 70 of the digital circuit board 62 is disposed upright along the left end of the driver circuit board 31 and the shield case 71 of the scaler circuit board 63 is disposed upright along the back end of the driver circuit board 31. Furthermore, the shield case 70 of the digital circuit board 62 disposed upright along the left end of the driver circuit board 31 is disposed between the power supply circuit board 60, analog signal processing substrate 61 and driver circuit board 31 so as to separate the power supply circuit board 60, analog signal processing substrate 61 from the driver circuit board 31. The shield case 71 of the scaler circuit board 63 disposed upright along the back end of the driver circuit board 31 is interposed between the projection unit 30 and lower cabinet 5 facing the uprising section 35b of the support frame 35 which fixes the projection unit 30 and three sides of the driver circuit board 31 are surrounded by these shield cases 70, 71 and the uprising section 35b of the support frame 35. Furthermore, since the driver circuit board 31 is covered with a shield case 39 fixed to the support frame 35 as described above, it is reliably shielded against electromagnetic waves and since the three sides thereof are surrounded by the shield cases 70, 71 and the uprising section 35b of the support frame 35, it is possible to effectively prevent noise from the scaler circuit board 63 or digital circuit board 62 from getting mixed in with the driver circuit board 31. Especially, the digital circuit board 62 is subject to harmonic noise due to a CH frequency or the like radiated from a digital tuner mounted on the digital circuit board 62 and designed to obtain an analog signal through D/A conversion of a digital signal, and so the clock frequency becomes an extremely high frequency, high-frequency noise radiated from the digital circuit board 62 reaches an extremely high level and if the high-frequency noise radiated from the digital circuit board 62 is modulated according to image information and gets mixed in with the driver circuit board 31 which forms an optical image, noise gets mixed in with the video image displayed on the screen 50, and therefore it is important to control noise which gets mixed in with the driver circuit board 31. Furthermore, the shield case 70 which accommodates the digital circuit board 62 is disposed upright so as to separate the driver circuit board 31 from the power supply circuit board 60 and analog signal processing substrate 61, and therefore it is also possible to inhibit the mixing of noise between the power supply circuit board 60, analog signal processing substrate 61 and digital circuit board 62. Furthermore, the lamp drive circuit board 64 is disposed on the lamp unit 20 side and close to the lamp 21, which facilitates the wiring between the lamp 21 and lamp drive circuit board 64, but the lamp drive circuit board 64 generates a high voltage (approximately 1000 V) to turn on the lamp 21, which causes high-frequency noise to be produced. However, since the lamp drive circuit board 64 is disposed at a position as far as possible from the analog signal processing substrate 61 with the projection unit 30 interposed in between, it is possible to effectively inhibit the mixing of noise radiated from the lamp drive circuit board 64 into the analog signal processing substrate 61.

As described above, according to this embodiment, the support frame 35 which fixes the projection unit 30 includes the bottom plate 35a and uprising section 35b and is formed in substantially an L shape and fixed above the uprising section 35b so as to cause the projection unit 30 to float from the bottom plate 35a and form the space 38 in which the driver circuit board 31 is disposed between the projection unit 30 and the bottom plate 35a, the driver circuit board 31 is fixed in this space 38, and therefore it is possible to arrange the driver circuit board 31 and the projection unit 30 in the vertical direction in such a way that part of the driver circuit board 31 overlaps with the projection unit 30. This allows the projection unit 30 fixed to the support frame 35 and the driver circuit board 31 to be unitized in a compact manner. Furthermore, the projection unit 30 can be set to the highest possible position within a range not interfering with the optical path R of an optical image reflected from the reflecting mirror 40, and it is thereby possible to suppress the total height of the rear projector 1. Furthermore, the uprising section 35b is tilted inward by 30° with respect to the normal and the optical axis 32a of the projection lens 32 can be tilted toward the back cabinet 6. This allows the reflecting mirror 40 which reflects an optical image from the projection lens 32 to tilt by 1.5° in the uprising direction, and can thereby make the cabinet 2, or by extension, the rear projector 1 slimmer.

Furthermore, the projection unit 30 is disposed at substantially the center of the lower cabinet 5 through the support frame 35 and the power supply circuit board 60 and analog signal processing substrate 61 are arranged side by side backward and forward on one side of the projection unit 30 centered on the projection unit 30, and the lamp drive circuit board 64 is disposed on the other side of the projection unit 30, and in this way a wide space in which apparatuses such as a disk storage/reproduction unit and/or hard disk unit can be mounted is formed above the power supply circuit board 60 and analog signal processing substrate 61 arranged side by side backward and forward, and when these storage/reproduction devices are combined as a composite machine, it is possible to effectively use the space. Furthermore, it is possible to arrange the analog signal processing substrate 61 and the lamp drive circuit board 64 which generates high-frequency noise at positions as far as possible from each other with the projection unit 30 interposed in between, effectively inhibiting the mixing of noise from the lamp drive circuit board 64 which becomes a noise source into the analog signal processing substrate 61. Furthermore, by covering the digital circuit board 62, scaler circuit board 63 and driver circuit board 31 with the shield cases 70, 71, 39, it is possible to enhance a shielding characteristic against electromagnetic noise and by interposing the shield case 70 which houses the digital circuit board 62 between the power supply circuit board 60, analog signal processing substrate 61 and driver circuit board 31 in an upright position so as to separate the power supply circuit board 60, analog signal processing substrate 61 from the driver circuit board 31, it is possible to inhibit the mixing of noise between the power supply circuit board 60, analog signal processing substrate 61 and driver circuit board 31. Furthermore, the three sides of the driver circuit board 31 are surrounded by the shield cases 70, 71 which house the digital circuit board 62, the scaler circuit board 63 and the uprising section 35b of the support frame 35, and it is thereby possible to effectively inhibit the mixing of noise into the driver circuit board 31.

Furthermore, the lamp 21 housed in the lamp housing 22 needs to be replaced when it reaches the end of its life cycle, but when the lamp 21 is replaced, the opening 11 formed on the side of the lower cabinet 5 is opened and the lamp 21 is replaced from the lamp replacement opening 22a of the lamp housing 22, and since the space between the lamp unit 20 and opening 11 is a substrate unmounted area 67 where no circuit board or electronic parts exist, it is possible to prevent the operator from mistakenly touch the circuit board and electronic parts inside the cabinet 2, allow the operator to carry out the operation safely and eliminate the possibility of provoking electrical trouble due to short-circuits. Furthermore, the working opening 29 which can be opened/closed is formed on the front of the lower cabinet 5 to allow the user to put the hand H into the housing through the working opening 29 to focus the projection unit 30 and fix the projection lens 32 after the focusing, and therefore the operator can carry out focusing of the projection lens 32 while checking with a screen projected on the screen 50, which provides excellent maintenability.

An embodiment of the present invention has been described in detail so far, but the present invention is not limited to this embodiment and can be implemented modified in various ways within a range not departing from the essence of the present invention. For example, the focusing mechanism of the projection unit can be selected as appropriate. Furthermore, the shapes and mounting structures of the cabinet and respective components are not limited to the embodiment and can be selected as appropriate.

The rear-projection type imaging device according to the first aspect of the present invention is a rear-projection type imaging device including a lamp unit, a projection unit which modulates a beam projected from the lamp unit according to image information, forms an optical image and projects an enlarged image of the optical image, a reflecting mirror which reflects the optical image projected from the projection unit, a screen exposed on one side of the housing, for projecting the optical image from the reflecting mirror and a housing which houses the lamp unit, projection unit, reflecting mirror and screen, wherein a support frame for integrating the projection unit and a driver circuit board which drives the projection unit and fixing the projection unit and driver circuit board to the housing is provided, the support frame comprises at least a bottom plate fixed to the housing and an uprising plate standing from one end of the bottom plate, the projection unit is fixed to the uprising plate so as to float from the bottom plate and at least part of the driver circuit board is disposed in a space formed between the projection unit and the bottom plate and the driver circuit board is fixed to the bottom plate, and therefore it is possible to mount the projection unit as close as possible to the screen, suppress the total height of the housing to a low level and thereby reduce the sizes of the device. Furthermore, the space in which the driver circuit board is disposed is formed between the projection unit and the bottom plate, the space can be effectively used as the space for mounting the driver circuit board, and therefore it is possible to eliminate any unnecessary space for mounting the driver circuit board in the housing.

The rear-projection type imaging device according to the second aspect of the present invention is the rear-projection type imaging device according to the first aspect of the present invention, wherein the housing includes at least a power supply circuit board which supplies power to a drive control section or the like of the optical unit, a digital circuit board which processes a digital signal such as a video signal sent from a digital tuner or the like, an analog signal processing substrate which processes an analog signal such as an audio signal sent from an external terminal or the like and a scaler circuit board which converts a display format based on the signal sent from the analog signal processing substrate, shield cases which cover at least the driver circuit board, digital circuit board and scaler circuit board are provided, the shield cases housing the digital circuit board and scaler circuit board are disposed upright close to two sides intersecting each other at right angles of the driver circuit board and the shield cases and uprising plate of the support frame are arranged so as to surround three sides of the driver circuit board, and therefore it is possible to assure electromagnetic shielding and effectively suppress high-frequency noise or the like which gets mixed in with the driver circuit board.

The rear-projection type imaging device according to the third aspect of the present invention is the rear-projection type imaging device according to the second aspect of the present invention, wherein the projection unit is disposed at substantially the center of the housing, the analog signal processing substrate and power supply circuit board are arranged side by side on one side of the projection unit and the shield case which houses the digital circuit board is interposed between the analog signal processing substrate, power supply circuit board and driver circuit board so that the shield case separates the analog signal processing substrate and power supply circuit board from the driver circuit board, and therefore it is possible to effectively suppress the mixing of high-frequency noise between the substrates. Furthermore, a wide space in which apparatuses such as a disk storage/reproduction unit and/or hard disk unit can be mounted is formed above the analog signal processing substrate and the power supply circuit board arranged side by side, and when these storage/reproduction devices are combined as a composite machine, it is possible to effectively use the space.

The rear-projection type imaging device according to the fourth aspect of the present invention is the rear-projection type imaging device according to the third aspect of the present invention, further comprising a lamp drive circuit board which drives the lamp unit, wherein the lamp drive circuit board is disposed at a position far from the analog signal processing substrate with the projection unit interposed in between, and therefore it is possible to effectively inhibit the mixing of noise radiated from the lamp drive circuit board into the analog signal processing substrate.

The rear-projection type imaging device according to the fifth aspect of the present invention is the rear-projection type imaging device according to the first aspect of the present invention, wherein a lamp replacement section for attaching/detaching the lamp provided in the lamp unit is formed in a substrate unmounted area inside the housing, and therefore it is possible to prevent the operator from mistakenly touching the circuit board or electronic parts in the cabinet when replacing the lamp and thereby allow the operator to perform replacement of the lamp safely.

The rear-projection type imaging device according to the sixth aspect of the present invention is the rear-projection type imaging device according to the first aspect of the present invention, wherein the projection unit comprises a focusing function which focuses the projection lens and a working opening which allows the focusing function to be operated from outside the housing is provided on the front side of the housing, and therefore the operator can perform focusing of the projection unit while checking a screen projected on the screen, which provides excellent maintenability.

What is claimed is:

1. A rear-projection type imaging device comprising:
a lamp unit;
a projection unit which modulates a beam projected from the lamp unit according to image information, forms an optical image and projects an enlarged image of the optical image;
a reflecting mirror which reflects the optical image projected from the projection unit;
a screen exposed on one side of the housing, for projecting the optical image from the reflecting mirror; and
a housing which houses the lamp unit, projection unit, reflecting mirror and screen,
wherein a support frame for integrating the projection unit and a driver circuit board which drives the projection unit and fixing the projection unit and driver circuit board to the housing is provided,
the support frame comprises at least a bottom plate fixed to the housing and an uprising plate standing from one end of the bottom plate,
the projection unit is fixed to the uprising plate so as to float from the bottom plate, and
at least part of the driver circuit board is disposed in a space formed between the projection unit and the bottom plate and the driver circuit board is fixed to the bottom plate.

2. The rear-projection type imaging device according to claim 1, wherein the housing includes at least a power supply circuit board which supplies power to a drive control section or the like of the optical unit, a digital circuit board which processes a digital signal such as a video signal sent from a digital tuner or the like, an analog signal processing substrate which processes an analog signal such as an audio signal sent from an external terminal or the like and a scaler circuit board which converts a display format based on the signal sent from the analog signal processing substrate,
shield cases which cover at least the driver circuit board, digital circuit board and scaler circuit board are provided,
the shield cases housing the digital circuit board and scaler circuit board are disposed upright close to two sides intersecting each other at right angles of the driver circuit board, and
the shield cases and uprising plate of the support frame are arranged so as to surround three sides of the driver circuit board.

3. The rear-projection type imaging device according to claim 2, wherein the projection unit is disposed at substantially the center of the housing,
the analog signal processing substrate and power supply circuit board are arranged side by side on one side of the projection unit, and
the shield case which houses the digital circuit board is interposed between the analog signal processing substrate, power supply circuit board and driver circuit board so that the shield case separates the analog signal processing substrate and power supply circuit board from the driver circuit board.

4. The rear-projection type imaging device according to claim 3, further comprising a lamp drive circuit board which drives the lamp unit,
wherein the lamp drive circuit board is disposed at a position far from the analog signal processing substrate with the projection unit interposed in between.

5. The rear-projection type imaging device according to claim 1, wherein a lamp replacement section for attaching/detaching the lamp provided in the lamp unit is formed in a substrate unmounted area inside the housing.

6. The rear-projection type imaging device according to claim 1, wherein the projection unit comprises a focusing function which focuses the projection lens, and
a working opening which allows the focusing function to be operated from outside the housing is provided on the front side of the housing.
